(19) United States
(12) Patent Application Publication
(10) Pub. No.: US 2011/0176286 A1
(43) Pub. Date: Jul. 21, 2011

(54) LEAD PIN AND WIRING SUBSTRATE WITH LEAD PIN

(75) Inventors: Shigeo NAKAJIMA, Nagano (JP); Yoshitaka Matsushita, Nagano (JP)

(73) Assignee: SHINKO ELECTRIC INDUSTRIES CO., LTD., Nagano-shi (JP)

(21) Appl. No.: 12/987,439

(22) Filed: Jan. 10, 2011

(30) Foreign Application Priority Data
Jan. 21, 2010 (JP) 2010-010842

(51) Int. Cl. H05K 1/11; H05K 7/00

(52) U.S. Cl. 361/783; 174/261

(57) ABSTRACT

A lead pin includes a shaft portion, and a connection head portion which is provided on a top end side of the shaft portion and has a diameter larger than a diameter of the shaft portion, and whose whole outer surface is formed of a spherical surface. The connection head portion is formed of a ball shape, an oval spherical shape, or a teardrop-like shape, and also the connection head portion of the lead pin is connected to a wiring substrate by the reflow soldering.

### CROSS-REFERENCE TO RELATED APPLICATIONS

This application is based upon and claims the benefit of priority of the prior Japanese Patent Application No. 2010-010842, filed on filed on Jan. 21, 2010, the entire contents of which are incorporated herein by reference.

### FIELD

It is related to a lead pin and a wiring substrate with lead pin.

### BACKGROUND

In the prior art, as the wiring substrate on which the electronic component is mounted, there is the PGA (Pin Grid Array) type wiring substrate. In the PGA type wiring substrate, a plurality electrode pads onto which the electronic component is connected are provided on one surface, while a plurality of lead pins which are inserted into the socket on the mother board are provided upright in a lattice arrangement on the other surface.

In Patent literature 1 (Japanese Laid-open Patent Publication No. 2002-223064), it is set forth that lead pins whose upper end surfaces are made substantially flat are provided upright to the pin attachment pad provided to the insulating substrate via the solder layer.

In Patent literature 2 (Japanese Laid-open Patent Publication No. 01-313970), it is set forth that a concave portion is formed on an end surface of the lead pin, and the brazing material is fixed to the concave portion by the caulking.

In Patent literature 3 (Japanese Laid-open Patent Publication No. 04-63467), it is set forth that a concave portion whose cross section of a tip part is formed wider than that of a base part is formed on an end surface of the lead pin, and the brazing material is fixed to the end surface thereof by the caulking.

In Patent literature 4 (Japanese Laid-open Patent Publication No. 03-270060), it is set forth that, in a head pin which is bonded to an electrode pad of a package substrate, the head pin is formed into a cone shape whose bottom surface is used as a bonding surface with the electrode pad.

As explained in the column of the related art described later, when the connection head portion of the lead pin is fixed to the pin connection portion of the wiring substrate by the soldering, in some case voids may occur in the solder layer on the top end surface side of the connection head portion. In the lead pin having the connection head portion whose top end surface is made flat, on account of the influence of the void, sufficient pin strength cannot be obtained and also the lead pin is fixed in an inclined state.

### SUMMARY

According to one aspect discussed herein, there is provided a shaft portion, and a connection head portion which is provided on a top end side of the shaft portion and has a diameter larger than a diameter of the shaft portion, and whose whole outer surface is formed of a spherical surface.

### BRIEF DESCRIPTION OF THE DRAWINGS

FIG. 1 is a sectional view depicting a state of soldering a connection head portion of a flat type lead pin onto a pin connection portion of a wiring substrate in the related art;

FIG. 2 is a side elevation depicting a lead pin according to a first embodiment;

FIG. 3 is a sectional view depicting an example of a wiring substrate to which the lead pin is fitted;

FIG. 4 is a sectional view depicting a state of fixing the lead pin in FIG. 2 to a pin connection portion of the wiring substrate by the soldering;

FIG. 5 is a sectional view depicting a state in which a semiconductor chip is mounted on a wiring substrate with lead pin in FIG. 4;

FIGS. 6A to 6C are sectional views depicting a state in which a lead pin according to a second embodiment is fitted to a wiring substrate; and

FIGS. 7A to 7C are sectional views depicting a state in which a lead pin according to a third embodiment is fitted to a wiring substrate.

### DESCRIPTION OF EMBODIMENTS

Embodiments will be explained with reference to the accompanying drawings hereinafter.

(Related Art)

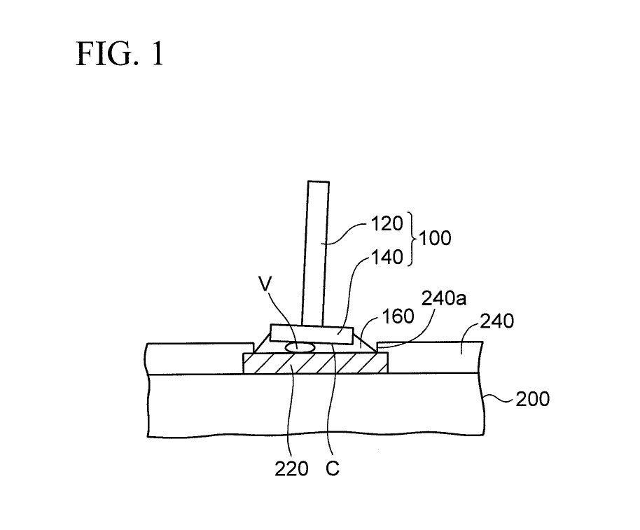

Prior to the explanation of embodiments, the related art (preliminary matter) will be explained hereunder. FIG. 1 is a sectional view depicting a state of fitting a lead pin onto a wiring substrate in the related art.

A lead pin 100 in the related art is constructed by a shaft portion 120, and a connection head portion 140 whose diameter is larger than the shaft portion 120. The lead pin 100 includes the flat-type connection head portion 140, and the connection head portion 140 has a flat bonding surface C over a whole area.

Also, a wiring substrate 200 to which the lead pin 100 is to be connected is prepared. The wiring substrate 200 includes a pin connection portion 220 on one surface side, and a solder resist 240 in which an opening portion 240a is provided on the pin connection portion 220 is provided on one surface side.

Also, a solder paste is coated on the pin connection portion 220, and the connection head portion 140 of the lead pin 100 is arranged on the solder paste. Then, the reflow soldering is executed by applying the heating process, and thus the lead pin 100 is bonded and fixed to the pin connection portion 220 of the wiring substrate 200 via a solder layer 160.

At this time, a void V (cavity) is easily generated in the solder layer 160 on the bonding surface C side of the lead pin 100. The void V is generated due to such an event that a volatile component produced when a solvent of the solder is vaporized is not sufficiently degassed and is stagnant. In the related art, the bonding surface C of the connection head portion 140 of the lead pin 100 is flat over the whole area, so that a volatile component of the solder is hard to degas and thus the void V is easily left in the center part of the bonding surface C of the connection head portion 140.

Therefore, in the lead pin 100 including the flat-type connection head portion 140, it is easily influenced by the void V, thus such a failure is easily caused that sufficient pin strength cannot be obtained and the lead pin 100 is fixed in an inclined state.

As the result of the earnest study of the related art mentioned above, the inventor of this application developed the lead pin having such a new shape that is hardly influenced by the void even though the void is generated in the solder layer when the lead pins are soldered onto the wiring substrate.

### First Embodiment

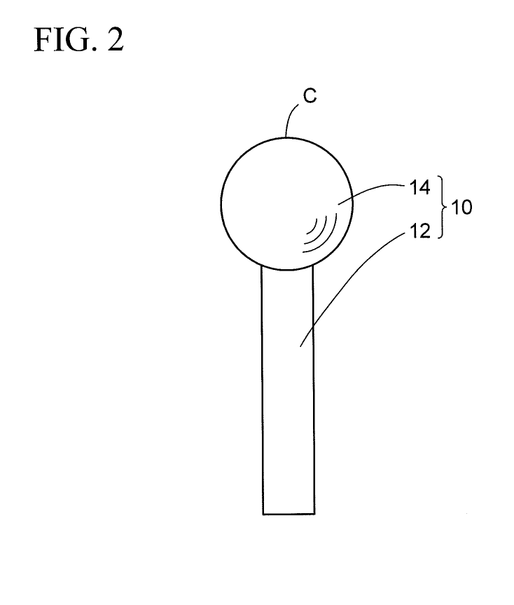

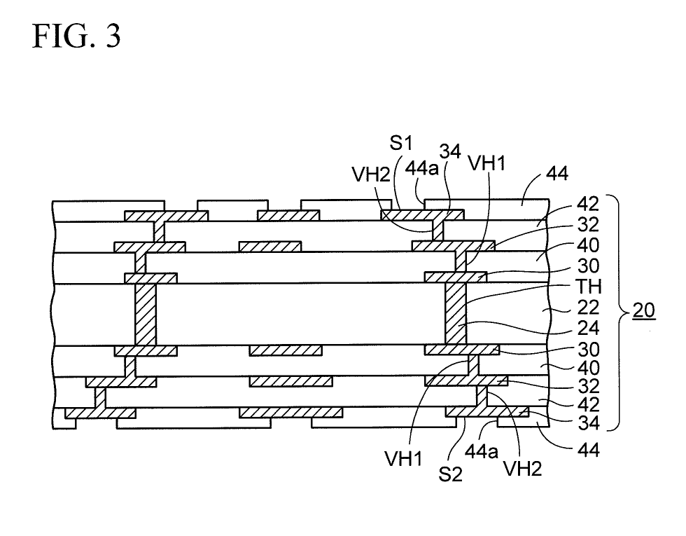

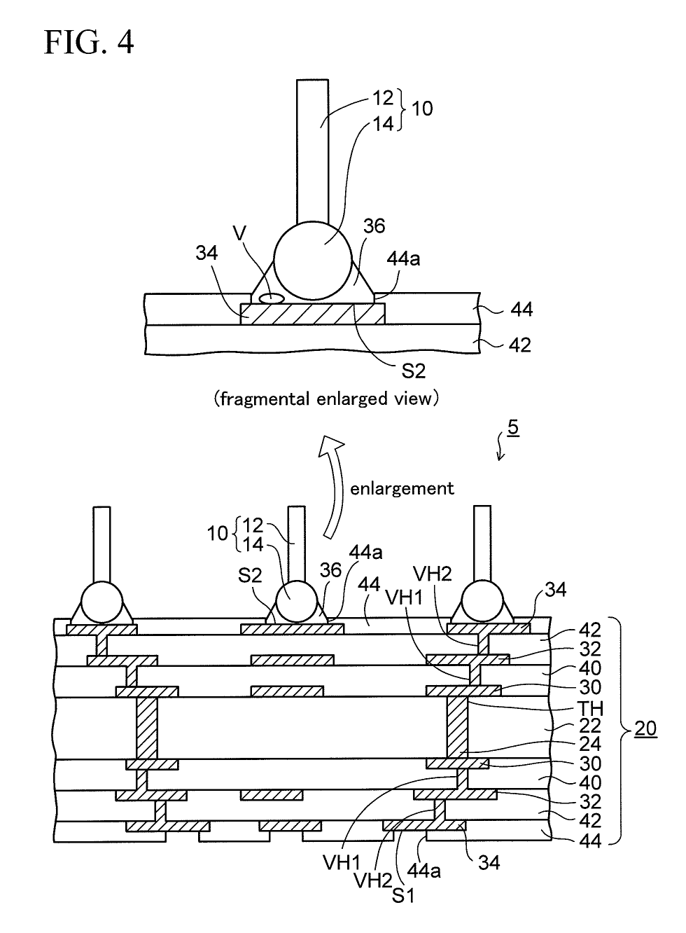

FIG. 2 is a side elevation depicting a lead pin according to a first embodiment, FIG. 3 is a sectional view depicting an example of a wiring substrate to which the lead pin is fitted, and FIG. 4 is a sectional view depicting a state of fixing the lead pin in FIG. 2 to the wiring substrate by the soldering.

As depicted in FIG. 2, a lead pin 10 according to the first embodiment is constructed by a shaft portion 12 having a cylinder-shape, and a connection head portion 14 which has a diameter larger than the shaft portion 12 and is provided on the top end side of the shaft portion 12. The shaft portion 12 and the connection head portion 14 are formed from an identical metal integrally.

The connection head portion 14 of the lead pin 10 is formed like a ball shape whose whole outer surface is formed of a spherical surface, and has a bonding surface C on the top end side. That is, the connection head portion 14 of the lead pin 10 of the first embodiment is formed of the ball shape whose diameters in the lateral direction and the vertical direction are identical.

The lead pin 10 is formed of copper (Cu), Cu alloy, nickel (Ni)-iron (Fe)-cobalt (Co) alloy (Kovar), or the like. A plating layer may be formed on a surface of the lead pin 10 so as to protect the lead pin 10 or improve the wettability with the solder. As the plating layer, a gold plating layer, from the pin surface sequentially, nickel/gold plating layer, or nickel/palladium/gold plating layer, is employed.

The other end side (the opposite side to the connection head portion 14 side) of the shaft portion 12 of the lead pin 10 acts as the connection part to the socket of the mother board.

Next, a method of fitting the lead pin 10 in FIG. 2 to the wiring substrate will be explained hereunder. As depicted in FIG. 3, first, a wiring substrate 20 to which the lead pins are connected is prepared. In the wiring substrate 20, through holes TH are provided in a core substrate 22, and penetration electrodes 24 are formed in the through holes TH. Also, first wiring layers 30 connected mutually via the penetration electrodes 24 are formed on both surface sides of the core substrate 22 respectively.

Also, a first interlayer insulating layers 40 is formed on both surface sides of the core substrate 22 respectively. Also, first via holes VH1 each reaching the first wiring layer 30 are formed in the first interlayer insulating layer 40 on both surface sides respectively.

Also, second wiring layers 32 each connected to the first wiring layer 30 via the first via hole VH1 (via conductor) are formed on the first interlayer insulating layer 40 on both surface sides of the core substrate 22 respectively.

Also, similarly a second interlayer insulating layer 42 in which second via holes VH2 each reaching the second wiring layer 32 are provided is formed on the second wiring layers 32 on both surface sides of the core substrate 22 respectively.

Also, similarly third wiring layers 34 each connected to the second wiring layer 32 via the second via hole VH2 (via conductor) are formed on the second interlayer insulating layer 42 on both surface sides respectively.

Also, a solder resist 44 in which opening portions 44a are provided on the connection part of the third wiring layer 34 is formed on both surface sides of the core substrate 22 respectively. The opening portion 44a of the solder resist 44 is opened as a circular shape when viewed from the top.

The connection part of the third wiring layer 34 on the upper surface side of the core substrate 22 acts as a chip connection portion S1 for connecting a semiconductor chip. Also, the connection part of the third wiring layer 34 on the lower surface side of the core substrate 22 acts as a pin connection portion S2 for fitting the lead pin. A contact layer (not shown) such as a Ni/Au plating layer, or the like is formed on the surfaces of the chip connection portion S1 and the pin connection portion S2 respectively.

In this manner, the wiring substrate 20 employed in the present embodiment includes the pin connection portions S2 on one surface and includes the chip connection portions S1 on the other surface. As the wiring substrate, various substrates such as a coreless substrate having no core substrate, etc. can be employed.

Then, as depicted in FIG. 4, the wiring substrate 20 in FIG. 3 is reversed up and down to direct the pin connection portions S2 upwardly. In turn, a solder paste is coated on the pin connection portions S2 of the wiring substrate 20, and then the connection head portions 14 of the lead pins 10 in FIG. 2 are placed on the solder pastes.

Then, the reflow soldering is executed by applying the heating process at about 260° C. Thus, the connection head portion 14 of the lead pin 10 is connected to the pin connection portion S2 of the wiring substrate 20 via a solder layer 36 and is fixed thereto. As the solder, lead/tin/antimony-based solder, tin/antimony-based solder, or the like may be employed.

In the lead pin 10 of the present embodiment, the whole of the outer surface of the connection head portion 14 is formed of a spherical surface. Therefore, the void generated in the solder layer 36 can be easily discharged to the outside, and the void is hard to occur in the solder layer 36.

At this time, as depicted in fragmental enlarged view in FIG. 4, even though the void V is generated in the solder layer 36, such void V is located in the position that is displaced outwardly from a center part of the connection head portion 14 of the lead pin 10. The reason for this is that, because the connection head portion 14 of the lead pin 10 is formed like a ball shape and thus the side edge part is chamfered, a volatile component of the solder is easily moved outward. In addition, a further advantage can be provided that a volatile component of the solder is easily degassed and thus a size of the void V can be made smaller even when the void V still remains in the solder layer 36.

Accordingly, even when the void V remains in the solder layer 36, the lead pin 10 is hardly influenced by the void in contrast to the related art. As a result, sufficient pin strength can be obtained, and also such a situation can be prevented that the lead pin 10 is fixed in an inclined state.

Further, the connection head portion 14 of the lead pin 10 of the first embodiment is formed of the ball shape. Therefore, even when plenty of solder paste is coated, such a situation can be prevented the solder layer 36 crawls up to the shaft portion 12 side, and reliability of the lead pin 10 can be secured.

This is because the moving amount of the solder in the lateral direction is particularly large and therefore the solder is hard to move and crawl up along a spherical surface. Not only the adhesion of the solder onto the shaft portion 12 causes a bad appearance, but also the adhesion of the solder up to the center part of the shaft portion 12 causes a connection failure between the lead pin 10 and the wiring substrate. As a result, the above adhesion of the solder is not preferable.

On the contrary, in the flat-type lead pin 100 (FIG. 1) in the related art, the back side (the opposite surface to the bonding surface C) of the connection head portion 140 is also made flat. Therefore, when plenty of solder paste is coated, the solder is easy to adhere onto the shaft portion 120 side.

With the above, a wiring substrate with lead pin 5 of the first embodiment can be obtained. As depicted in FIG. 4, in the wiring substrate with lead pin 5 of the first embodiment, the ball-shaped connection head portion 14 of the lead pin 10 is connected to the pin connection portion S2 of the wiring substrate 20 explained in FIG. 3 by the solder layer 36, and is fixed thereto.

In the example in FIG. 4, an interval (the solder layer 36) is present between the connection head portion 14 of the lead pin 10 and the pin connection portion S2 of the wiring substrate 20. In this case, the connection head portion 14 of the lead pin 10 and the pin connection portion S2 of the wiring substrate 20 may be contacted directly and soldered mutually.

By reference to FIG. 4, a diameter of the pin connection portion S2 of the wiring substrate 20 and a diameter of the connection head portion 14 of the lead pin 10 will be mentioned hereunder. It is preferable that a diameter of the connection head portion 14 should be set to 40% to 80% of a diameter of the pin connection portion S2. The pin connection portion S2 corresponds to the area of the third wiring layer 34, which is exposed from the opening portion 44a in the solder resist 44, and has a circular shape when viewed from the top.

Accordingly, a void V which is generated in the solder layer 36 is located to deviate more outward from a center part of the connection head portion 14 of the lead pin 10. Therefore, a structure that is suitable for the securing of pin strength and the prevention of an inclination of the pin is obtained.

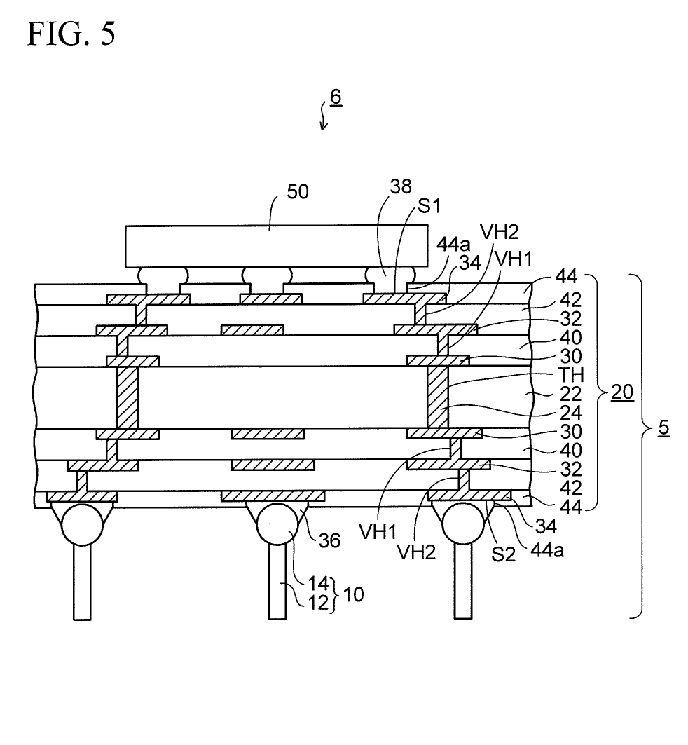

Then, as depicted in FIG. 5, the wiring substrate with lead pin 5 in FIG. 4 is reversed up and down to direct the chip connection portions S1 upward. Then, a semiconductor chip 50 (LSI chip) is prepared, and then the connection electrodes of the semiconductor chip 50 are arranged on the chip connection portions S1 of the wiring substrate 20 via the solder balls, or the like.

Then, the reflow soldering is executed by applying the heating process. Thus, the connection electrodes of the semiconductor chip 50 are flip-chip connected to the chip connection portions S1 of the wiring substrate 20 via a solder layer 38. Upon mounting the semiconductor chip 50, the solder whose melting temperature is lower than the solder layer 36 for the lead pin 10 is employed such that the solder layer 36 fixing the lead pin 10 does not reflow again.

As a result, the semiconductor chip 50 is mounted on the wiring substrate with lead pin 5, and a semiconductor device 6 (a semiconductor package) is constructed.

As described above, in the present embodiment, the lead pin 10 including the connection head portion 14 having the ball shape is hardly affected by the void V in the solder layer 36 rather than the related art. Therefore, the sufficient pin strength can be obtained, and also such a situation can be prevented that the lead pin 10 is fixed in an inclined state. As a result, the wiring substrate with lead pin 5 with high reliability and the semiconductor device 6 utilizing this wiring substrate can be constructed.

### Second Embodiment

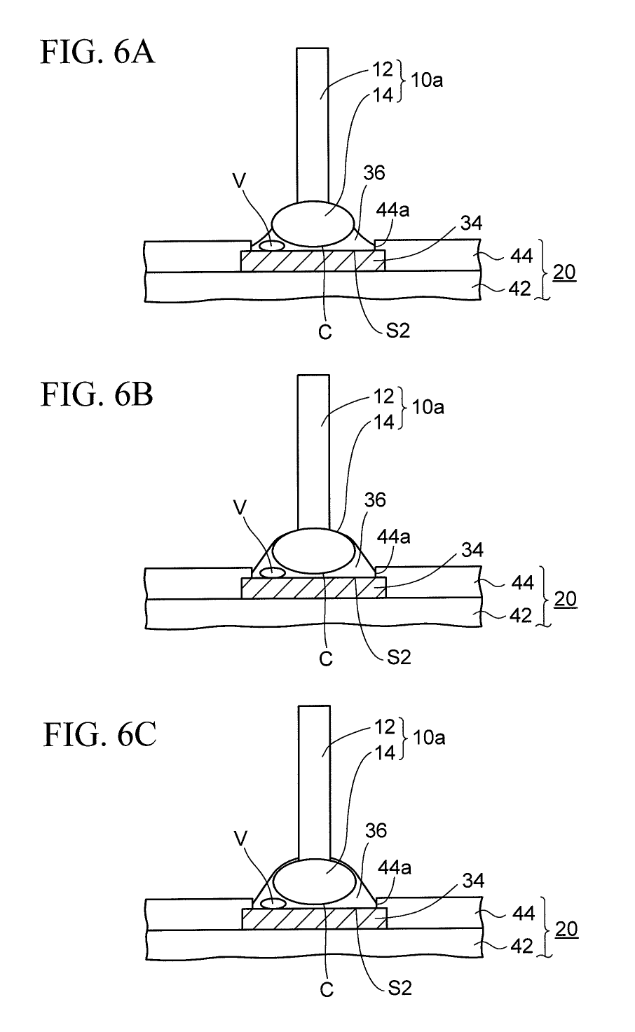

FIGS. 6A to 6C are sectional views depicting a state in which a lead pin according to a second embodiment is fitted to a wiring substrate.

As depicted in FIG. 6A, like the first embodiment, a lead pin 10a of the second embodiment is constructed by the shaft portion 12, and the connection head portion 14 which has a diameter larger than a diameter of the shaft portion 12 and is provided on the top end side of the shaft portion 12.

A difference of the second embodiment from the first embodiment resides in that the connection head portion 14 is formed of an oval spherical shape whose whole outer surface is formed of a spherical surface, and has the bonding surface C on the top end side. That is, the connection head portion 14 is formed of an oval sphere having a lateral long shape, whose diameter in the lateral direction is set longer than a diameter in the vertical direction.

Then, the connection head portion 14 of the lead pin 10a is connected to the pin connection portion S2 of the wiring substrate 20 similar to the first embodiment via the solder layer 36, and is fixed thereto. At this time, like the first embodiment, even when the void V is generated in the solder layer 36, such void V is located in the position that is displaced outward from a center part of the connection head portion 14 of the lead pin 10a.

Accordingly, the lead pin 10a is hardly affected by the void V rather than the related art. As a result, the sufficient pin strength can be obtained, and such a situation can be prevented that the lead pin 10a is fixed in an inclined state.

Remaining constitutions are similar to the lead pin 10 of the first embodiment, and the wiring substrate with lead pin and the semiconductor device similar to those in the first embodiment can be constructed.

In FIG. 6A, the solder layer 36 is formed from the pin connection portion S2 of the wiring substrate 20 to the center part of the side surface of the connection head portion 14 of the lead pin 10a. But the solder layer 36 may be formed up to the arbitrary position of the connection head portion 14.

As depicted in FIG. 6B, the major part of the connection head portion 14 of the lead pin 10a except the neighborhood of its coupling part with the shaft portion 12 may be buried in the solder layer 36. Otherwise, as depicted in FIG. 6C, the whole of the connection head portion 14 of the lead pin 10a may be buried in the solder layer 36.

In the second embodiment, the connection head portion 14 of the lead pin 10a and the pin connection portion S2 of the wiring substrate 20 may be contacted directly and be soldered mutually.

Also, like the first embodiment, it is preferable that a diameter of the connection head portion 14 of the lead pin 10a (a diameter in the lateral direction) should be set to 40% to 80% of a diameter of the pin connection portion S2 of the wiring substrate 20.

The lead pin 10a of the second embodiment can achieve the similar advantages to those of the first embodiment.

In this event, in the lead pin 10 of the first embodiment, the whole of the connection head portion 14 having the spherical shape, of the lead pin 10 may be buried in the solder layer 36.

### Third Embodiment

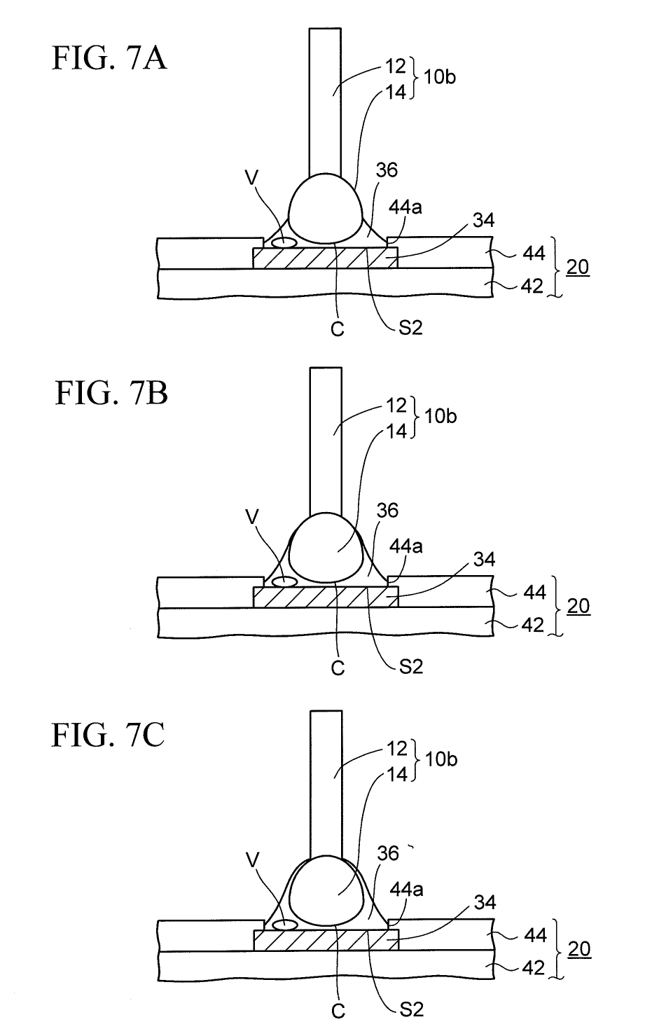

FIGS. 7A to 7C are sectional views depicting a state in which a lead pin according to a third embodiment is fitted to a wiring substrate.

As depicted in FIG. 7A, like the first embodiment, a lead pin 10b of the third embodiment is constructed by the shaft portion 12, and the connection head portion 14 which has a diameter larger than a diameter of the shaft portion 12 and is provided on the top end side of the shaft portion 12.

A difference of the third embodiment from the first embodiment resides in that the connection head portion 14 is formed of a teardrop-like shape whose whole outer surface is formed of a spherical surface, and has the bonding surface C on the top end side. In other words, when viewed from the side, a part of the maximum diameter (maximum width) of the connection head portion 14 is arranged in the position that is displaced from the center part in the vertical direction to the top end side of the lead pin 10b, and the connection head portion 14 is formed of a spherical shape that is asymmetrical in the vertical direction.

Also, the connection head portion 14 of the lead pin 10b is connected to the pin connection portion S2 of the wiring substrate 20 similar to the first embodiment via the solder layer 36 and is fixed thereto. At this time, like the first embodiment, even when the void V is generated in the solder layer 36, such void V is located in the position that is displaced outward from the center part of the connection head portion 14 of the lead pin 10b.

Accordingly, the lead pin 10b is hardly affected by the void V rather than the related art. As a result, the sufficient pin strength can be obtained, and such a situation can be prevented that the lead pin 10b is fixed in an inclined state.

Remaining constitutions are similar to the lead pin 10 of the first embodiment, and the wiring substrate with lead pin and the semiconductor device similar to those in the first embodiment can be constructed.

In FIG. 7A, like the second embodiment, the solder layer 36 is formed from the pin connection portion S2 of the wiring substrate 20 to the center part of the side surface of the connection head portion 14 of the lead pin 10b. But the solder layer 36 may be formed up to the arbitrary position of the connection head portion 14.

As depicted in FIG. 7B, the major part of the connection head portion 14 of the lead pin 10b except the neighborhood of its coupling parts with the shaft portion 12 may be buried in the solder layer 36. Otherwise, as depicted in FIG. 7C, the whole of the connection head portion 14 of the lead pin 10b may be buried in the solder layer 36.

In the third embodiment, the connection head portion 14 of the lead pin 10b and the pin connection portion S2 of the wiring substrate 20 may be contacted directly and soldered mutually.

Also, in the third embodiment, it is preferable that a diameter (a maximum diameter in the lateral direction) of the connection head portion 14 of the lead pin 10b should be set to 40% to 80% of a diameter of the pin connection portion S2 of the wiring substrate 20.

The lead pin 10b of the third embodiment can achieve the similar advantages to those of the first embodiment.

With the above, in the first to third embodiments, as the preferred example of the shape of the connection head portion of the lead pin, the ball shape, the oval spherical shape, and the teardrop-like shape are depicted respectively. In this event, the various spherical shapes whose diameter is larger than that of the shaft portion and in which the whole of the outer surface is formed of the spherical surface may be employed, thus the similar advantages can be achieved.

All examples and conditional language recited herein are intended for pedagogical purpose to aid the reader in understanding the invention and the concepts contributed by the inventor to furthering the art, and are to be construed as being without limitation to such specifically recited examples and conditions, nor does the organization of such examples in the specification relates to a showing of the superiority and interiority of the invention. Although the embodiments of the present invention have been described in detail, it should be understood that the various changes, substitutions, and alterations could be made hereto without departing from the spirit and scope of the invention.

What is claimed is:

1. A lead pin, comprising:
a shaft portion; and
a connection head portion which is provided on a top end side of the shaft portion and has a diameter larger than a diameter of the shaft portion, and whose whole outer surface is formed of a spherical surface.

2. A lead pin according to claim 1, wherein the connection head portion is formed of a ball shape, an oval spherical shape whose diameter in a lateral direction is longer than a diameter in a vertical direction, or a teardrop-like shape whose part of maximum diameter is arranged in a position that is displaced from a center part in the vertical direction to a top end side.

3. A wiring substrate with lead pin, comprising:
the lead pin set forth in claim 1; and
a wiring substrate including a pin connection portion;
wherein the connection head portion of the lead pin is connected to the pin connection portion of the wiring substrate via a solder layer.

4. A wiring substrate with lead pin, according to claim 3, wherein the wiring substrate includes a chip connection portion on an opposite surface to a surface on which the pin connection portion is provided, and
a semiconductor chip is connected to the chip connection portion of the wiring substrate.

5. A wiring substrate with lead pin, according to claim 3, wherein a diameter of the connection head portion of the lead pin is set to 40 to 80% of a diameter of the pin connection portion of the wiring substrate.

6. A wiring substrate with lead pin, according to claim 3, wherein the solder layer is formed of a solder paste, and
In the case that a void is generated in the solder layer, the void is located in a position that is displaced outward from a center part of the connection head portion of the lead pin.
